(19) United States
(12) Patent Application Publication
(10) Pub. No.: US 2025/0308891 A1
(43) Pub. Date: Oct. 2, 2025

(54) METHOD OF MANUFACTURING NITRIDE SEMICONDUCTOR DEVICE AND NITRIDE SEMICONDUCTOR DEVICE

(71) Applicant: SANKEN ELECTRIC CO., LTD., Niiza-Shi (JP)

(72) Inventor: Ken SATO, Niiza-Shi (JP)

(73) Assignee: SANKEN ELECTRIC CO., LTD., Niiza-Shi (JP)

(21) Appl. No.: 19/090,488

(22) Filed: Mar. 26, 2025

(30) Foreign Application Priority Data
Mar. 29, 2024 (JP) 2024-056329

(51) Int. Cl. H01L 21/02; H10D 30/01; H10D 30/47; H10D 62/60; H10D 62/85

(52) U.S. Cl. CPC H01L 21/0262; H10D 30/015; H10D 30/475; H10D 30/476; H10D 62/60; H10D 62/8503

(57) ABSTRACT

A method of manufacturing a nitride semiconductor device according to one or more embodiments is disclosed that includes forming a first nitride semiconductor layer, forming a second nitride semiconductor layer having a higher carrier concentration than the first nitride semiconductor layer on the first nitride semiconductor layer, forming a third nitride semiconductor layer on the second nitride semiconductor layer, forming a fourth nitride semiconductor layer on the third nitride semiconductor layer, forming a first main electrode electrically connected to the first nitride semiconductor layer, forming a second main electrode electrically connected to the fourth nitride semiconductor layer, and forming a control electrode on the third nitride semiconductor layer via an insulating film. In one or more embodiments, during the forming the second nitride semiconductor layer, the second nitride semiconductor layer is formed with higher carbon concentration than the carbon concentration of the first nitride semiconductor layer.

### CROSS REFERENCE TO RELATED APPLICATIONS

The application claims priority to prior Japanese Patent Application No. 2024-056329 filed with the Japan Patent Office on Mar. 29, 2024, the entire contents of which are incorporated herein by reference.

### BACKGROUND

The disclosure relates to a method for manufacturing a nitride semiconductor device and a nitride semiconductor device.

The structure of a semiconductor device using a nitride-based compound semiconductor (GaN-based) is disclosed, for example, in FIG. 4 of JP2017-063174 (Patent Document 1).

Patent Document 1 discloses that the low concentration carrier region 121 is provided on the substrate 110, the high concentration carrier region 123 is provided on the low concentration carrier region 121, the low concentration carrier region 125 is provided on the high concentration carrier region 123, and the p-type semiconductor layer 130 forming a channel is provided on the low concentration carrier region 125. The n-type semiconductor layer 140 is provided on the p-type semiconductor layer 130, the n-type semiconductor layer 140 and the source electrode 174 are electrically connected, the substrate 110 and the drain electrode 178 are electrically connected, the gate electrode 172 is formed through an insulating film 160 in the trench 152 which penetrates the p-type semiconductor layer 130 and reaches the low concentration carrier region 125.

In the disclosed structure, the high concentration carrier region 123 is provided on the low concentration carrier region 121 that functions as a drift region. The high concentration carrier region 123 distributes the current so that the current flowing through the channel generated along the side wall of the trench 152 flows more dispersed in the surface direction in the low concentration carrier region 121. In addition, there is a description that the carrier concentration of the low concentration carrier region 121 and the low concentration carrier region 125 is substantially the same (paragraph 0030 of Patent Document 1).

The patent literature 1 discloses that the donor element contained in the n-type semiconductor layer may be not limited to silicon (Si) but may also be germanium (Ge) and oxygen (O). Further, Patent Document 1 discloses that the acceptor element contained in the p-type semiconductor layer may be not limited to magnesium (Mg) but also zinc (Zn), carbon (C), and the like (paragraphs 0007 and 0008 of Patent Document 1).

In Patent Document 1, since the p-type semiconductor layer 130 generates a channel, the MOVPE method capable of precise film thickness and doping control is used, and the MOVPE method is also used for the low concentration carrier region 121 (Paragraph 0031 of Patent Document 1).

However, the low concentration carrier region 121 needs to be formed relatively thick at a relatively low donor concentration in order to secure the breakdown voltage of the semiconductor device. Here, in the MOVPE method, carbon is doped in the nitride-based compound semiconductor layer, but the amount of carbon doped varies greatly depending on the growth temperature and other factors. The low concentration carrier region 121 is a relatively thick layer formed at a relatively low donor concentration. For this reason, the variation in the carrier concentration in the low concentration carrier region 121 may become a problem that leads to a variation in the breakdown voltage of the semiconductor device.

According to the method for manufacturing the nitride semiconductor device and the nitride semiconductor device according to one or more embodiments, the variation in the carrier concentration in the low concentration carrier region and the variation in the breakdown voltage of the nitride semiconductor device resulting therefrom may be reduced.

Further, according to one or more embodiments, a nitride semiconductor device having low on-resistance and high breakdown voltage and a manufacturing method thereof may be provided.

### SUMMARY

The method of manufacturing nitride semiconductor device according to one or more embodiments may comprise: forming a first nitride semiconductor layer of the first conductive type; forming a second nitride semiconductor layer of the first conductive type having a higher carrier concentration than the first nitride semiconductor layer on the first nitride semiconductor layer; forming a third nitride semiconductor layer of the second conductive type on the second nitride semiconductor layer; forming a fourth nitride semiconductor layer of the first conductive type on the third nitride semiconductor layer; forming a first main electrode electrically connected to the first nitride semiconductor; forming a second main electrode electrically connected to the fourth nitride semiconductor layer; and forming a control electrode on the third nitride semiconductor layer via an insulating film. The method for manufacturing a nitride semiconductor device according to one or more embodiments, in any period from the start of the forming the second nitride semiconductor layer until the completion of the forming he second nitride semiconductor layer, the carbon concentration of the second nitride semiconductor layer may be higher than the carbon concentration of the first nitride semiconductor layer.

In such a method for manufacturing a nitride semiconductor device, the carbon concentration is higher than that of the first nitride semiconductor layer at any point during the deposition of the second nitride semiconductor layer, which has a higher carrier concentration than the first nitride semiconductor layer, that is, the first nitride semiconductor layer has a lower carrier concentration than the second nitride semiconductor layer but also has a lower carbon concentration. By suppressing the carbon concentration of the first nitride semiconductor layer, the carrier concentration of the first nitride semiconductor layer may be suppressed. In addition, although the second nitride semiconductor layer has a higher carbon concentration, at the same time it includes a high concentration carrier region having a higher carrier concentration than the first nitride semiconductor layer, therefore, even if the carbon concentration of the second nitride semiconductor layer is increased, the carrier concentration of the second nitride semiconductor layer is also high, it may be possible to suppress the fluctuations in the carbon concentration on the carrier concentration, thereby reducing variations in carrier concentration due to fluctuations in carbon concentration. As a result, the nitride semiconductor device having low on-resistance and high breakdown voltage may be manufactured. In this case, the region in which the carbon concentration of the second nitride semiconductor layer is increased may be the entire thickness region or only a part of the thickness region, that is, only the upper thickness region.

Further, the film formation of the first nitride semiconductor layer is performed by the HVPE method, and the second nitride semiconductor layer may be formed by switching from the HVPE method to the MOVPE method after the deposition of the second nitride semiconductor layer starts and before the completion of deposition of the second nitride semiconductor layer.

In such a method for manufacturing a nitride semiconductor device, the HVPE method is a method that has a faster growth rate and less carbon contamination than the MOVPE method, and by forming a film of the first nitride semiconductor layer by the HVPE method, the carbon concentration of the first nitride semiconductor layer may be reduced, and the influence of fluctuations in carbon concentration on the carrier concentration may be suppressed, and the variations in carrier concentration may be suppressed.

Further, between the second nitride semiconductor layer and the third nitride semiconductor layer, the fifth nitride semiconductor layer of the first conductive type having a lower carrier concentration than the second nitride semiconductor layer may be formed, and the carrier concentration of the fifth nitride semiconductor layer may be higher than the carrier concentration in the first nitride semiconductor layer.

In such a method for manufacturing a nitride semiconductor device, the carrier concentration of the fifth nitride semiconductor layer is lower than the second nitride semiconductor layer and higher than the first nitride semiconductor layer, thereby suppressing the effect of carbon concentration fluctuations on the carrier concentration more than in the first nitride semiconductor layer, thereby suppressing the variation in carrier concentration. Furthermore, since the depletion layer spreads from the interface between the third nitride semiconductor layer of the second conductive type and the fifth nitride semiconductor layer in contact with each other, by suppressing the influence of fluctuations in carbon concentration on the carrier concentration, the variation in the breakdown voltage of the nitride semiconductor device caused thereby may be reduced.

Further, the oxygen peak concentration of the second nitride semiconductor layer may be higher than the oxygen peak concentration of the first nitride semiconductor layer.

In such a method for manufacturing a nitride semiconductor device, the donor concentration may be further increased in the second nitride semiconductor layer, which has a higher carrier concentration than the first nitride semiconductor layer.

Further, in the second half of the forming the second nitride semiconductor layer, the carbon concentration of the second nitride semiconductor layer may be higher than the carbon concentration of the first nitride semiconductor layer.

If such a nitride semiconductor device manufacturing method is used, the influence of fluctuations in the carbon concentration in the first nitride semiconductor layer may be suppressed, and variations in the carrier concentration may be suppressed.

The nitride semiconductor device according to one or more embodiments may comprise: the first nitride semiconductor layer of the first conductive type; the second nitride semiconductor layer of the first conductive type stacked on the first nitride semiconductor layer and having a higher carrier concentration than that of the first nitride semiconductor layer; the third nitride semiconductor layer of the second conductive type stacked on the second nitride semiconductor layer; the fourth nitride semiconductor layer of the first conductive type stacked on the third nitride semiconductor layer; the first main electrode electrically connected to the first nitride semiconductor layer and the second main electrode electrically connected to the fourth nitride semiconductor layer; and the control electrode provided via an insulating film on the third nitride semiconductor layer. In the nitride semiconductor device according to one or more embodiments, in the second nitride semiconductor layer, the carbon concentration at least in the upper part may be higher than the carbon concentration of the first nitride semiconductor layer.

In such a nitride semiconductor device, the first nitride semiconductor layer is a low concentration carrier region having a lower carrier concentration than the second nitride semiconductor layer, but at the same time, the carbon concentration itself is also lower, which suppresses the effect of carbon concentration fluctuations on the carrier concentration and reduces the variation of the carrier concentration. Therefore, the variation in the carrier concentration of the low concentration carrier region and the variation in the breakdown voltage of the nitride semiconductor device caused thereby may be reduced. In addition, the second nitride semiconductor layer has a high carbon concentration at least in the upper part, but at the same time has a high carrier concentration region with a higher carrier concentration than the first nitride semiconductor layer, thus suppressing the effect of carbon concentration variation on the carrier concentration and reducing carrier concentration variation. As a result, the nitride semiconductor device may have a low on-resistance and high breakdown voltage.

Further, between the second nitride semiconductor layer and the third nitride semiconductor layer, the fifth nitride semiconductor layer of the first conductive type having a lower carrier concentration than the second nitride semiconductor layer may be included, and the carrier concentration of the fifth nitride semiconductor layer may be higher than the carrier concentration in the first nitride semiconductor layer.

In such a nitride semiconductor device, the carrier concentration of the fifth nitride semiconductor layer is lower than the second nitride semiconductor layer and higher than the first nitride semiconductor layer, so that the effect of the variation of the carbon concentration on the carrier concentration is suppressed and the variation of the carrier concentration is reduced more than in the first nitride semiconductor layer. Furthermore, since the depletion layer spreads from the interface between the third nitride semiconductor layer of the second conductive type and the fifth nitride semiconductor layer in contact with each other, the influence of fluctuations in carbon concentration on the carrier concentration may be suppressed, thus reducing the variation in breakdown voltage of the nitride semiconductor device caused thereby.

Further, the oxygen peak concentration of the second nitride semiconductor layer may be higher than the oxygen peak concentration of the first nitride semiconductor layer.

In such a nitride semiconductor device, the donor concentration may be further increased in the second nitride semiconductor layer, which has a higher carrier concentration than that of the first nitride semiconductor layer.

Further, the second nitride semiconductor layer may have a higher carbon concentration at the upper part than at the bottom.

In such a nitride semiconductor device, the effect of fluctuations in the carbon concentration in the first nitride semiconductor layer may be suppressed, and the variation in the carrier concentration may be reduced.

### BRIEF DESCRIPTION OF DRAWINGS

FIG. 1 is a diagram illustrating a cross-sectional view of a nitride semiconductor device and a manufacturing method according to one or more embodiments.

FIG. 2 is a chart illustrating changes in each carrier concentration in each nitride semiconductor layer according to one or more embodiments.

FIG. 3 is a chart illustrating changes in donor concentrations in each nitride semiconductor layer according to one or more embodiments.

FIG. 4 is a diagram illustrating a cross-sectional view of a nitride semiconductor device according to a related technology.

### DETAILED DESCRIPTION

As described above, there has been a demand for a method for manufacturing a nitride semiconductor device and a nitride semiconductor device in which the variation in the breakdown voltage of the nitride semiconductor device that is caused by the variation of the carrier concentration in the low concentration carrier region are reduced.

Therefore, during the deposition of the second nitride semiconductor layer, which has a higher carrier concentration than the first nitride semiconductor layer, the effect of the fluctuation of the carbon concentration on the carrier concentration may be suppressed and the variation of the carrier concentration may be reduced by increasing the carbon concentration of the second nitride semiconductor layer higher than the carbon concentration of the first nitride semiconductor layer.

That is, the method for manufacturing a nitride semiconductor device according to one or more embodiments manufactures a nitride semiconductor device that may include the first nitride semiconductor layer of the first conductive type, the second nitride semiconductor layer of the first conductive type stacked on the first nitride semiconductor layer and having a higher carrier concentration than the first nitride semiconductor layer, the third nitride semiconductor layer of the second conductive type stacked on the second nitride semiconductor layer, the fourth nitride semiconductor layer of the first conductive type stacked on the third nitride semiconductor layer, the first main electrode electrically connected to the first nitride semiconductor layer, the second main electrode electrically connected to the fourth nitride semiconductor layer, and the control electrode provided on the third nitride semiconductor layer via the insulating film. In one or more embodiments, the first nitride semiconductor layer, the second nitride semiconductor layer, the third nitride semiconductor layer, and the fourth nitride semiconductor layer may be formed in that order, the carbon concentration of the second nitride semiconductor layer may be higher than the carbon concentration of the first nitride semiconductor layer at any time between the start and the end of forming the second nitride semiconductor layer.

Further, the nitride semiconductor device according to one or more embodiments may include the first nitride semiconductor layer of the first conductive type, the second nitride semiconductor layer of the first conductive type stacked on the first nitride semiconductor layer and having a higher carrier concentration than the first nitride semiconductor layer, the fourth nitride semiconductor layer of the first conductive type stacked on the third nitride semiconductor layer, the first main electrode electrically connected to the first nitride semiconductor layer, the second main electrode electrically connected to the fourth nitride semiconductor layer, and the control electrode provided on the third nitride semiconductor layer via an insulating film. In one or more embodiments, the second nitride semiconductor layer may have a carbon concentration at least an upper part that is higher than the carbon concentration of the first nitride semiconductor layer.

Hereinafter, the nitride semiconductor device and the method for manufacturing the nitride semiconductor device according to one or more embodiments are described in detail with reference to the drawings. In the following description, “upper” and “lower” do not indicate thickness, but may indicate a relative positional relationship. The thickness of the “top” and the thickness of the “bottom” may be the same thickness. The disclosure also includes cases where the thickness of the “upper part” may be thicker than the thickness of the “lower part” or the thickness of the “upper part” may be thinner than the thickness of the “lower part”. Further, “above” may include not only the case where a layer is formed in contact with another layer, but also the case where a layer is formed through another layer. Further, even if a layer is provided on the side of another layer, the term “above” may include the configuration as long as it is substantially the same as the configuration according to one or more embodiments. Further, in one or more embodiments, “connection” is not limited to direct connection n, and even if it is connected by intervening something such as a resistor in between, it belongs to the technical range as long as it is substantially the same as the configuration requirements of the present invention.

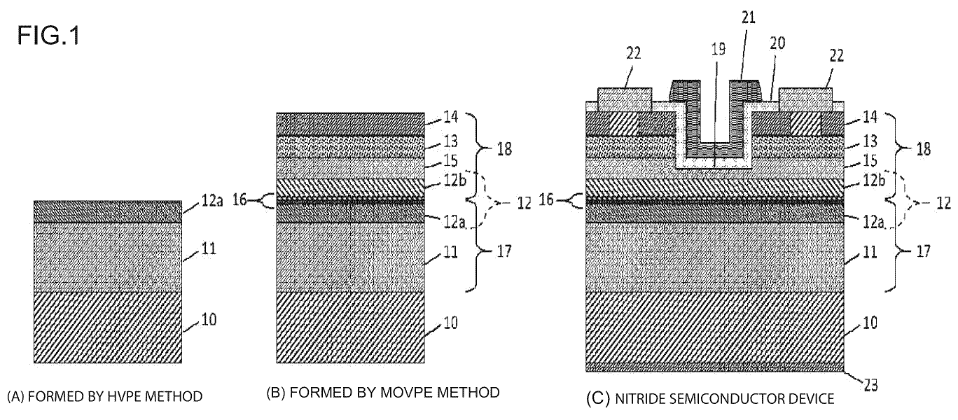

FIGS. 1A, 1B, and 1C are cross-sectional views illustrating an example of the nitride semiconductor device and the manufacturing method thereof according to one or more embodiments.

FIG. 1A is a cross-sectional view of the nitride semiconductor device according to one or more embodiments, in which the first half of the film is formed by the HVPE method. FIG. 1B is a cross-sectional view of the nitride semiconductor device according to one or more embodiments, in which the second half of the film is formed by the MOVPE method. FIG. 1C is a cross-sectional view of a nitride semiconductor device according to one or more embodiments.

As shown in FIG. 1A, the first nitride semiconductor layer 11 (for example, a low concentration carrier region) of the first conductive type (for example, N-type), and the first half 12a of the second nitride semiconductor layer 12 (for example, a high concentration carrier region) of the first conductive type (for example, N type) which has a higher carrier concentration than the first nitride semiconductor layer 11 are formed on the substrate 10 (e.g., a low resistance GaN substrate) by the HVPE method.

After the start of forming the second nitride semiconductor layer 12 and before the completion of the forming the second nitride semiconductor layer 12, the process is switched from the HVPE method to the MOVPE method. The second half 12b of the second nitride semiconductor layer 12, the fifth nitride semiconductor layer 15 (for example, a low concentration carrier region) of the first conductive type (N-type) having a lower carrier concentration than the second nitride semiconductor layer 12 and a higher carrier concentration than the first nitride semiconductor layer 11, the third nitride semiconductor layer 13 (for example, a p-type semiconductor layer) of the second conductive type (for example, p-type), and the fourth nitride semiconductor layer 14 (for example, an n-type semiconductor layer) of the first conductive type (N-type) are formed. Note that the thickness of the first half 12a of the second nitride semiconductor layer 12 and the thickness of the second half 12b of the second nitride semiconductor layer 12 (for example, the high concentration carrier region) may be substantially equal. Further, the thickness of the first half 12a of the second nitride semiconductor layer 12 and the thickness of the first half 12a of the second nitride semiconductor layer 12 (for example, the high concentration carrier region) may be thicker than the thickness of the second half 12b. Furthermore, the thickness of the first half 12a of the second nitride semiconductor layer 12 and the thickness of the first half 12a of the second nitride semiconductor layer 12 (for example, the high concentration carrier region) may be thinner than the thickness of the second half 12b.
the nitride semiconductor device may also include the first main electrode 23 (for example, a drain electrode) electrically connected to the substrate 10, the second main electrode 22 (source electrode) electrically connected to the fourth nitride semiconductor layer 14, and the control electrode 21 (gate electrode) provided via the insulating film 20 in the trench 19 that penetrates the third nitride semiconductor layer 13 and reaches the fifth nitride semiconductor layer 15.

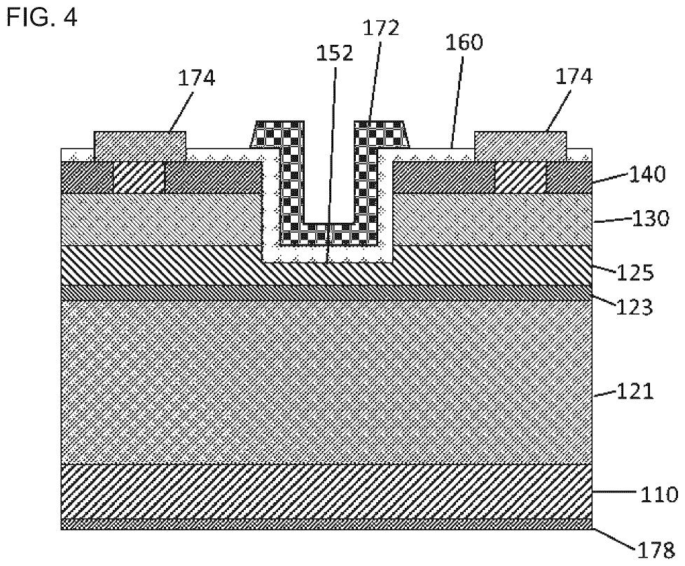

The semiconductor device illustrated in FIG. 4 only has the high concentration carrier region 123. On the other hand, one or more embodiments may differ in switching from the forming method of the first half 12a of the second nitride semiconductor layer 12 in the high concentration carrier region to the forming method of the second half 12b. Specifically, in one or more embodiments, the first half 12a of the second nitride semiconductor layer 12 in the high concentration carrier region may be formed by the HVPE method, and the second half of the second nitride semiconductor layer 12 in the high concentration carrier region may be formed by the MOVPE method.

Here, as a method for manufacturing the nitride semiconductor device according to one or more embodiments, the carbon concentration of the second nitride semiconductor layer 12 may be higher than that of the first nitride semiconductor layer 11 in any of the period from the start of forming of the second nitride semiconductor layer 12 to the end of the forming the second nitride semiconductor layer 12.

In the second half of the forming the second nitride semiconductor layer, it may be preferable that the carbon concentration of the second nitride semiconductor layer is higher than that of the first nitride semiconductor layer. Further, the carbon concentration may be increased from the first half of the forming the second nitride semiconductor layer.

Further, as the nitride semiconductor device according to one or more embodiments, the second nitride semiconductor layer 12 may have higher carbon concentration at least at the upper part than the carbon concentration of the first nitride semiconductor layer 11.

Note that it may be preferable that the second nitride semiconductor layer 12 has a higher carbon concentration at the upper part than at the lower part.

In this case, the carbon concentration of the first half 12a positioned at the lower part of the second nitride semiconductor layer 12 may be equivalent to the carbon concentration of the first nitride semiconductor layer 11, and the carbon concentration of the second half 12b located in the upper part of the second nitride semiconductor layer 12 may be higher than the carbon concentration of the first nitride semiconductor layer 11.

Since during the deposition of the second nitride semiconductor layer 12, which has a higher carrier concentration than the first nitride semiconductor layer 11, the carbon concentration of the second half 12b positioned at the upper part is higher than that of the first nitride semiconductor layer 11, that is, the carbon concentration itself is also low, although at the same time the first nitride semiconductor layer 11 has a lower carrier concentration than the second nitride semiconductor layer 12, the effect of fluctuations in carbon concentration on carrier concentration may be suppressed, and variations in carrier concentration may also be suppressed. Therefore, it may be possible to reduce the variation in the carrier concentration of the low concentration carrier region and the variation in the breakdown voltage of the nitride semiconductor device caused thereby. In addition, the second half 12b located in the upper part of the second nitride semiconductor layer 12 is a high concentration carrier region having a higher carbon concentration but at the same time having a higher carrier concentration than the first nitride semiconductor layer 11, and thus the effect of the variation of the carbon concentration on the carrier concentration may be suppressed and the variation of the carrier concentration may be suppressed. As a result, a nitride semiconductor device having low on-resistance and high breakdown voltage may be manufactured.

The first nitride semiconductor layer 11 may be formed by the HVPE method and then the formation method is switched from the HVPE method to the MOVPE method after the start of film formation of the second nitride semiconductor layer 12 before the end of the forming the second nitride semiconductor layer 12. The HVPE method is a method with less carbon contamination, and the MOVPE method is a method with some carbon contamination. By switching from the HVPE method to the MOVPE method, it may be possible to easily increase the carbon concentration during the process.

It may be preferable that the oxygen peak concentration of the second nitride semiconductor layer 12 is higher than the oxygen peak concentration of the first nitride semiconductor layer 11. Therefore, in one or more embodiments, an oxygen-containing region 16 is formed from the first half 12a located in the lower part of the second nitride semiconductor layer 12 to the second half 12b located in the upper part. The method for forming the oxygen-containing region 16 is not particularly limited, but may be formed by taking advantage of the tendency of oxygen to be mixed into the surface of the nitride semiconductor layer when the reactor is changed from the HVPE method to the MOVPE method.

As a result, in the second nitride semiconductor layer 12, which has a higher carrier concentration than the first nitride semiconductor layer 11, both the carbon concentration and the oxygen peak concentration are higher than the first nitride semiconductor layer 11, the concentrations of both carbon which may be a p-type acceptor element, and oxygen which may be an n-type donor element become higher, the carrier concentrations cancel out each other so that fluctuations in carrier concentration may be suppressed.

As described above, the produced nitride semiconductor device has a low carbon region 17 and a carbon-containing region 18 thereon. Although not particularly limited, the thickness of the low carbon region 17 may be 10 μm or more in order to ensure the breakdown voltage of the nitride semiconductor device. Further, the thickness may be set according to the breakdown voltage required for the nitride semiconductor device.

Here, one or more parts of the trench gate type nitride semiconductor device shown in FIG. 4 may be used to manufacture a nitride semiconductor device according to one or more embodiments. Further, it is not limited thereto and may be implemented in one or more embodiments. The bottom of the trench may not be in the low concentration carrier region 125 (which may correspond to the fifth nitride semiconductor layer 15) of FIG. 4, but may be in the deeper low concentration carrier region 121 (which may correspond to the first nitride semiconductor layer 11). Furthermore, the low concentration carrier region 125 (which may correspond to the fifth nitride semiconductor layer 15) may not necessarily be formed.

### Method of Manufacturing Nitride Semiconductor Device

In the method for manufacturing the nitride semiconductor device according to one or more embodiments, the first nitride semiconductor layer 11, which is a low concentration carrier region on the substrate, may be formed with a low donor concentration on the order of, for example, n×10¹⁵ [cm⁻³]. The concentration of carbon may be precisely controlled. Furthermore, although not particularly limited, the first nitride semiconductor layer 11, which is a low concentration carrier region, may be formed relatively thick in order to ensure a breakdown voltage. Therefore, it may be formed using an HVPE method that has a fast growth rate and low carbon contamination.

Then, the HVPE method is switched to the MOVPE method between the start of film formation of the second nitride semiconductor layer 12 (high concentration carrier region) on the first nitride semiconductor layer 11 (low concentration carrier region) and the end of the forming the second nitride semiconductor layer 12 (high concentration carrier region). The switch to the MOVPE method may be performed at the beginning of the formation of the second nitride semiconductor layer 12 (high concentration carrier region) or during the formation of the second nitride semiconductor layer 12 (high concentration carrier region).

In one or more embodiments, the carbon concentration of the second nitride semiconductor layer 12 (high concentration carrier region) is high, specifically, the carbon concentration of the second nitride semiconductor layer 12 (high concentration carrier region) is higher than the carbon concentration of the first nitride semiconductor layer 11 (low concentration carrier region). On the other hand, in the second nitride semiconductor layer 12 (high concentration carrier region), the n-type carrier concentration such as silicon (Si) is doped relatively higher than the carbon concentration (for example, about one digit higher). Therefore, even if the carbon concentration fluctuates slightly due to the influence of the growth temperature or the like, it may be unlikely to lead to variations in the carrier concentration, and the effect on the breakdown voltage of the nitride semiconductor device may be small.

Further, when the nitride semiconductor device is off, a depletion layer spreads from the interface between an n-type semiconductor layer in contact with the third nitride semiconductor layer 13, which is a p-type semiconductor layer (for example, a low concentration carrier region (for example, a fifth nitride semiconductor layer 15), or a high concentration carrier region (for example, the second nitride semiconductor layer 12) in the case of nitride semiconductor devices without the fifth nitride semiconductor layer 15). Since the depletion layer is quickly expanded to the low concentration carrier region (first nitride semiconductor layer 11) below the high concentration carrier region (second nitride semiconductor layer 12), the high concentration carrier region (for example, the second nitride semiconductor layer 12) is formed relatively thin. From this, even if the carbon concentration increases in the high concentration carrier region (for example, the second nitride semiconductor layer 12), the effect on the breakdown voltage of the nitride semiconductor device may be small.

In addition, the oxygen at the interface mixed when switching from the HVPE method to the MOVPE method may be used as a donor at the time of formation of a high concentration carrier region (for example, the second nitride semiconductor layer 12), and the carbon mixed after switching to the MOVPE method may be used as a high resistance (N-type suppression). The concentration in that case is as shown in the following example.

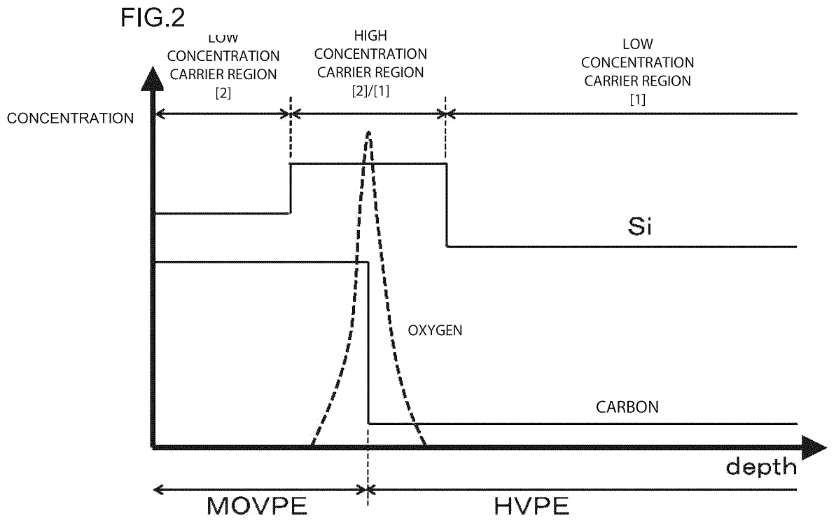

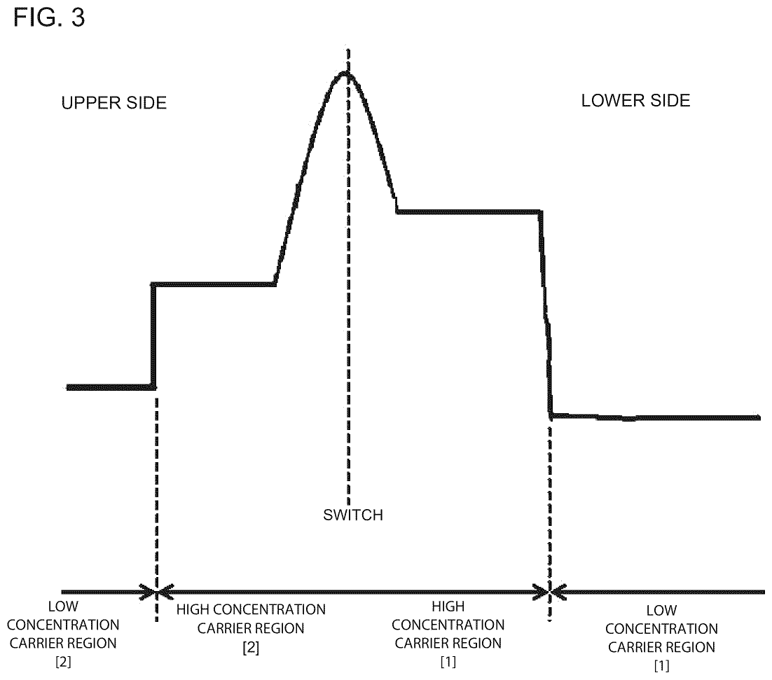

FIG. 2 is a chart showing changes in each carrier concentration, and FIG. 3 is a chart showing changes in donor concentrations. The low concentration carrier region [1] in the figure corresponds to the first nitride semiconductor layer 11 of FIG. 1, the high concentration carrier region [1] corresponds to the first half 12a of the second nitride semiconductor layer, the high concentration carrier region [2] corresponds to the second half 12b of the second nitride semiconductor layer, and the low concentration carrier region [2] corresponds to the fifth nitride semiconductor layer 15.

### <Low Concentration Carrier Region [1]>

First, refer to FIG. 2, and in the low concentration carrier region [1] formed by the HVPE method, the concentration of Si (silicon), which is the donor, is low, but the concentration of carbon as the acceptor is much lower.

Since the carbon concentration itself is low, the effect of fluctuations in carbon concentration on the carrier concentration (in this case, the donor concentration) may be suppressed, and the variation of the carrier concentration may be suppressed. Therefore, it may be possible to reduce the variation in the carrier concentration of the low concentration carrier region and the variation in the breakdown voltage of the nitride semiconductor device caused thereby.

### <High Concentration Carrier Region [1]>

Next, in the high concentration carrier region [1], the film is formed by the HVPE method, and the concentration of Si (silicon) is increased, and the concentration of carbon remains low.

Therefore, the difference between the concentration of Si and the concentration of carbon widens, and the effect of fluctuation of carbon concentration may be suppressed.

### <High Concentration Carrier Region [2]>

Next, switching to the MOVPE method, in a high concentration carrier region [2], the concentration of Si (silicon) remains high, but the concentration of carbon increases. In addition, at the time of switching, the concentration of oxygen as a donor also increases, and a peak of oxygen concentration occurs.

Here, higher carbon concentrations seem to increase the effect of variation in carbon concentration, however, the ratio of carbon concentration to donor concentration does not increase because the concentration of Si, which is a donor, is high to begin with and the concentration of oxygen, which is also a donor, is also high, so the effect of carbon concentration fluctuations may continue to be suppressed.

### <Low Concentration Carrier Region [2]>

Next, in the low concentration carrier region [2], the concentration of Si (silicon) decreases, but the concentration is higher than that of the low concentration carrier region [1], and the concentration of carbon remains high.

The effect of fluctuations in carbon concentration may be suppressed to some extent by not lowering the concentration of Si (silicon) in the low concentration carrier region [2] too much to the same level as the concentration of Si (silicon) in the low concentration carrier region [1].

This is expressed as a change in donor concentration (the difference between the donor and the acceptor), as shown in FIG. 3. The donor concentration is lowest in the low concentration carrier region [1], and does not go lower thereafter.

In this embodiment, since oxygen is doped when switching from the HVPE method to the MOVPE method, a peak occurs in the high concentration carrier region [1] and [2] by oxygen doping. If the amount of Si doped is not changed in the high concentration carrier region, the region above the switch is doped with acceptor carbon, so the concentration of the carrier that acts as a donor decreases relatively. The carrier concentration of the low concentration carrier region [2] is higher than the carrier concentration of the low concentration carrier region [1] in order to suppress the effect of the variation in the amount of carbon doped in the high concentration carrier region [2] and to suppress the variation in the breakdown voltage of the nitride semiconductor device. For example, as shown in FIG. 2, the amount of Si dope is increased.

The depletion layer spreads from the interface of the n-type semiconductor layer in contact with the p-type semiconductor layer. As shown in FIG. 3, the carrier concentration is lower in the upper part of the high concentration carrier region (high concentration carrier region [2]), which makes it easier for the depletion layer to spread within the high concentration carrier region, thus increasing the breakdown voltage of the semiconductor device.

The timing of switching from the HVPE method to the MOVPE method is not particularly limited, but it maya be preferable to switch before half of the final thickness of the high concentration carrier region. Thereby, it may be possible to reduce the suppression of the spread of the depletion layer due to a large increase in the carrier in the upper part of the high concentration carrier region by oxygen doping mixed by switching from the HVPE method to the MOVPE method.

### Nitride Semiconductor Device

The nitride semiconductor device according to one or more embodiments is described.

In the nitride semiconductor device according to one or more embodiments, the carbon concentration in the high concentration carrier region is higher than the carbon concentration in the low concentration carrier region [1]. As a result, the carbon concentration tends to vary due to manufacturing temperature conditions and the like, but by lowering the carbon concentration in the low concentration carrier region [1], even if the carrier concentration of the low concentration carrier region [1] is lowered, the effect of carbon dope under manufacturing temperature conditions and the like may be reduced, thereby providing with low breakdown voltage variation, relatively low on-resistance, and high breakdown voltage.

Further, it may be desirable that the carbon concentration in the upper part of the high concentration carrier region (high concentration carrier region [2]) is higher than the carbon concentration in the lower part of the high concentration carrier region (high concentration carrier region [1]). For example, as shown in FIG. 2, when the Si donor concentration in the high concentration carrier region ([1] and [2]) is constant in the thickness direction, the carrier concentration (donor concentration) of the upper part of the high concentration carrier region (high concentration carrier region [2]) is lower than the carrier concentration (donor concentration) of the lower part of the high concentration carrier region (high concentration carrier region [1]) (see FIG. 3). As a result, the depletion layer is relatively easy to spread in the upper part of the high concentration carrier region, and current dispersion is easy in the lower part. As described above, it may be possible to provide a nitride semiconductor device having a relatively low on-resistance and a high breakdown voltage.

In addition, by doping the high concentration carrier region with oxygen, the carrier concentration (donor concentration) of the high concentration carrier region may be increased.

As another embodiment, since oxygen in the device is doped on the semiconductor surface at the initial stage of the forming a low concentration carrier region [1], silicon may be formed without doping. Thereby, the crystallinity of the low concentration carrier region [1] may be increased.

The nitride semiconductor according to one or more embodiments and the method for manufacturing the same may encompass the following aspects.

Method of manufacturing nitride semiconductor device comprises the first nitride semiconductor layer of the first conductive type, the second nitride semiconductor layer of the first conductive type stacked on the first nitride semiconductor layer and having a higher carrier concentration than the first nitride semiconductor layer, the third nitride semiconductor layer of the second conductive type stacked on the second nitride semiconductor layer, and the fourth nitride semiconductor layer of the first conductive type stacked on the third nitride semiconductor layer, the first main electrode electrically connected to the first nitride semiconductor layer, the second main electrode electrically connected to the fourth nitride semiconductor layer, and a control electrode provided via an insulating film on the third nitride semiconductor layer. Method of manufacturing nitride semiconductor device comprises forming a film in the order of the first nitride semiconductor layer, the second nitride semiconductor layer, the third nitride semiconductor layer, and the fourth nitride semiconductor layer, the carbon concentration of the second nitride semiconductor layer is higher than the carbon concentration of the first nitride semiconductor layer at any time between the start of forming the second nitride semiconductor layer and the completion of forming of the second nitride semiconductor layer.

The forming of the first nitride semiconductor layer is performed by the HVPE method, then the HVPE method is switched to the MOVPE method to form the second nitride semiconductor layer between the start of film formation of the second nitride semiconductor layer and the completion of the forming the second nitride semiconductor layer.

The fifth nitride semiconductor layer of the first conductive type having a lower carrier concentration than the second nitride semiconductor layer is formed between the second nitride semiconductor layer and the third nitride semiconductor layer, and the carrier concentration of the fifth nitride semiconductor layer is higher than the carrier concentration in the first nitride semiconductor layer.

The oxygen peak concentration of the second nitride semiconductor layer is higher than the oxygen peak concentration of the first nitride semiconductor layer.

In the second half of the film forming the second nitride semiconductor layer, the carbon concentration of the second nitride semiconductor layer is higher than the carbon concentration of the first nitride semiconductor layer.

The nitride semiconductor device comprises the first nitride semiconductor layer of the first conductive type, the second nitride semiconductor layer of the first conductive type stacked on the first nitride semiconductor layer and having a higher carrier concentration than the first nitride semiconductor layer, and the third nitride semiconductor layer of the second conductive type stacked on the second nitride semiconductor layer, and the fourth nitride semiconductor layer of the first conductive type stacked on the third nitride semiconductor layer, the first main electrode electrically connected to the first nitride semiconductor layer, a second main electrode electrically connected to the fourth nitride semiconductor layer, and a control electrode provided via an insulating film on the third nitride semiconductor layer. The nitride semiconductor device wherein the carbon concentration of at least the upper portion of the second nitride semiconductor layer is higher than that of the first nitride semiconductor layer.

The fifth nitride semiconductor layer of the first conductive type having a lower carrier concentration than the second nitride semiconductor layer is included between the second nitride semiconductor layer and the third nitride semiconductor layer, and the carrier concentration of the fifth nitride semiconductor layer is higher than the carrier concentration in the first nitride semiconductor layer.

The oxygen peak concentration of the second nitride semiconductor layer is higher than the oxygen peak concentration of the first nitride semiconductor layer.

The second nitride semiconductor layer has a higher carbon concentration at the top than at the bottom.

The above embodiment is illustrative, and the technical idea includes any that has the same effect. For example, a semiconductor device having a trench MIS structure in which a trench 19 is provided on the nitride semiconductor layer surface and a gate electrode 21 is provided via an insulating film 20 is shown as an example, but it may be applied to a planar type semiconductor device in which a gate electrode is provided via an insulating film on a nitride semiconductor surface, for example a DMOSFET.

As described above, according to the method of manufacturing the nitride semiconductor device according to one or more embodiments, the carbon concentration is higher than that of the first nitride semiconductor layer in any point during the film forming the second nitride semiconductor layer having a higher carrier concentration than that of the first nitride semiconductor layer. That is, although the first nitride semiconductor layer is a low concentration carrier region having a lower carrier concentration than the second nitride semiconductor layer, at the same time the carbon concentration itself is low, the effect of fluctuations in carbon concentration on the carrier concentration may be suppressed. Therefore, it may be possible to reduce the variation in the carrier concentration of the low concentration carrier region and the variation in the breakdown voltage of the nitride semiconductor device caused thereby. In addition, although the second nitride semiconductor layer has a higher carbon concentration, it includes a high concentration carrier region having a higher carrier concentration than the first nitride semiconductor layer at the same time, therefore, the influence of fluctuations in carbon concentration on the carrier concentration may be suppressed, and variations in the carrier concentration may be reduced. As a result, a nitride semiconductor device having low on-resistance and high breakdown voltage may be manufactured.

Further, in the nitride semiconductor device according to one or more embodiments, in the second nitride semiconductor layer having a higher carrier concentration than the first nitride semiconductor layer, carbon concentration at least in the upper part is higher than the carbon concentration of the first nitride semiconductor layer. That is, although the first nitride semiconductor layer is a low concentration carrier region having a lower carrier concentration than the second nitride semiconductor layer, the carbon concentration itself is also low, so that the influence of fluctuations in the carbon concentration on the carrier concentration may be suppressed, and the variation of the carrier concentration may be reduced. Therefore, the variation in the carrier concentration of the low concentration carrier region and the variation in the breakdown voltage of the nitride semiconductor device caused thereby may be reduced. In addition, the second nitride semiconductor layer includes a high concentration carrier region having at least a higher carbon concentration at the upper part, but at the same time having a higher carrier concentration than the first nitride semiconductor layer, thus suppressing the effect of variations in carbon concentration on the carrier concentration and reducing variations in carrier concentration. As a result, the nitride semiconductor device may have a low on-resistance and high breakdown voltage.

1. A method of manufacturing a nitride semiconductor device comprising:
forming a first nitride semiconductor layer of a first conductive type;
forming a second nitride semiconductor layer of the first conductive type having a higher carrier concentration than the first nitride semiconductor layer on the first nitride semiconductor layer;
forming a third nitride semiconductor layer of a second conductive type on the second nitride semiconductor layer;
forming a fourth nitride semiconductor layer of the first conductive type on the third nitride semiconductor layer;
forming a first main electrode electrically connected to the first nitride semiconductor layer;
forming a second main electrode electrically connected to the fourth nitride semiconductor layer; and
forming a control electrode on the third nitride semiconductor layer via an insulating film, wherein
in a period from a start of the forming of the second nitride semiconductor layer until an end of the forming of the second nitride semiconductor layer, the second nitride semiconductor layer is formed with higher carbon concentration than a carbon concentration of the first nitride semiconductor layer.

2. The method of manufacturing the nitride semiconductor device according to claim 1, wherein
the forming the first nitride semiconductor layer comprises performing a HVPE method.

3. The method of manufacturing the nitride semiconductor device according to claim 2, wherein
the forming the second nitride semiconductor layer comprises switching the HVPE method to a MOVPE method to form the second nitride semiconductor layer between the start of the forming of the second nitride semiconductor layer and the end of the forming of the second nitride semiconductor layer.

4. The method of manufacturing the nitride semiconductor device according to claim 1, further comprising
forming a fifth nitride semiconductor layer of the first conductive type having a lower carrier concentration than the second nitride semiconductor layer between the second nitride semiconductor layer and the third nitride semiconductor layer.

5. The method of manufacturing the nitride semiconductor device according to claim 4, wherein
a carrier concentration of the fifth nitride semiconductor layer is higher than the carrier concentration of the first nitride semiconductor layer.

6. The method of manufacturing the nitride semiconductor device according to claim 1, wherein
an oxygen peak concentration of the second nitride semiconductor layer is higher than an oxygen peak concentration of the first nitride semiconductor layer.

7. The method of manufacturing the nitride semiconductor device according to claim 1, wherein
in a second half of the forming of the second nitride semiconductor layer, the carbon concentration of the second nitride semiconductor layer is higher than that of the first nitride semiconductor layer.

8. A nitride semiconductor device comprising:
a first nitride semiconductor layer of a first conductive type;
a second nitride semiconductor layer of the first conductive type on the first nitride semiconductor layer and having a higher carrier concentration than that of the first nitride semiconductor layer;
a third nitride semiconductor layer of a second conductive type on the second nitride semiconductor layer;
a fourth nitride semiconductor layer of the first conductive type on the third nitride semiconductor layer;
a first main electrode electrically connected to the first nitride semiconductor layer and a second main electrode electrically connected to the fourth nitride semiconductor layer; and
a control electrode positioned on the third nitride semiconductor layer through an insulating film, wherein a carbon concentration of at least an upper portion of the second nitride semiconductor layer is higher than the carbon concentration of the first nitride semiconductor layer.

9. The nitride semiconductor device according to claim 8, further comprising:
a fifth nitride semiconductor layer of the first conductive type having a lower carrier concentration than the second nitride semiconductor layer, the fifth nitride semiconductor layer positioned between the second nitride semiconductor layer and the third nitride semiconductor layer; wherein
the carrier concentration of the fifth nitride semiconductor layer is higher than the carrier concentration of the first nitride semiconductor layer.

10. The nitride semiconductor device according to claim 8, wherein
an oxygen peak concentration of the second nitride semiconductor layer is higher than an oxygen peak concentration of the first nitride semiconductor layer.

11. The nitride semiconductor device according to claim 8, wherein
the second nitride semiconductor layer has a higher carbon concentration in an upper part than in a lower part.
